(19) United States
(12) Patent Application Publication
(10) Pub. No.: US 2010/0136768 A1
(43) Pub. Date: Jun. 3, 2010

(54) METHOD FOR SIMULTANEOUS DOPING AND OXIDIZING SEMICONDUCTOR SUBSTRATES AND THE USE THEREOF

(75) Inventors: Daniel Biro, Freiburg (DE); Ralf Preu, Freiburg (DE); Jochen Rentsch, Emmendingen (DE)

Correspondence Address: FAEGRE & BENSON LLP;PATENT DOCKETING - INTELLECTUAL PROPERTY, 2200 WELLS FARGO CENTER, 90 SOUTH SEVENTH STREET, MINNEAPOLIS, MN, 55402-3901, US

(73) Assignee: Fraunhofer-Gesellschaft zur Forderung der Angewandten Forschung E.V., Munchen (DE)

(21) Appl. No.: 12/439,964

(22) PCT Filed: Sep. 4, 2007
(86) PCT No.: PCT/EP07/07703

§ 371 Date: Feb. 9, 2010

(30) Foreign Application Priority Data
Sep. 4, 2006 (DE) 10 2006 041 424.1

(51) Int. Cl. H01L 21/22; H01L 21/322

(52) U.S. Cl. 438/471; 438/565; 257/E21.135; 257/E21.318

(57) ABSTRACT

The invention relates to a method for simultaneous doping and oxidizing semiconductor substrates and also to doped and oxidized semiconductors substrates produced in this manner. Furthermore, the invention relates to the use of this method for producing solar cells.

### CROSS-REFERENCE TO RELATED APPLICATIONS

The present application is a national phase application of PCT application PCT/EP2007/007703 filed pursuant to 35 U.S.C. §371, which claims priority to DE 10 2006 041 424.1 filed Sep. 4, 2006. Both applications are incorporated herein by reference in their entirety.

### FIELD OF THE INVENTION

The invention relates to a method for simultaneous doping and oxidizing semiconductor substrates and also to doped and oxidized semiconductor substrates produced in this manner. Furthermore, the invention relates to the use of this method for producing solar cells.

### BACKGROUND

Modern solar cells can include doped regions close to the surface, for example for producing a p-n junction or so-called front- or back-surface field. A phosphorus diffusion into p-doped silicon can be applied for emitter production. Furthermore, excellent solar cells have dielectrically passivated surface regions that suppress the recombination of charge carrier pairs and also advantageously affect the optical properties of the semiconductor component. Layers of this type can be produced with PVD methods or by thermal processes. In the case of silicon dioxide on silicon, thermal oxidation is implemented in the presence of oxygen and, for a moist oxidation, with the additional presence of water vapor. Currently, these process steps are implemented sequentially, as a result of which the production of solar cells is made complicated since it contains at least one thermal diffusion process and one oxidation process. If these steps are implemented sequentially, further additional steps ensure that, in the process steps, only the regions of the wafers provided for this purpose are processed, e.g. masking or etching steps.

Diffusion of doping atoms can be effected in different ways. In some cases, a doping agent source is present, from which the doping agent is transferred into the silicon under suitable conditions. This doping source can be present in the gaseous atmosphere, e.g. POCl₃, or can be deposited by suitable methods, e.g. phosphoric acid can be sprayed on. Furthermore, CVD processes can be used in order to produce doped layers.

In the process of ion implantation, the doping atoms are implanted in the wafer by subjecting the wafer to high-energy particle beams containing doping atoms. The atoms then penetrate into the wafer and the doping is activated in a subsequent annealing step at increased temperature and distributed around as desired. During activation, the atoms forced into the crystal lattice move towards free lattice sites and then can serve as doping agent. During distribution, by means of diffusion of the doping atoms, the concentration profile of the doping atoms is changed by diffusion within the semiconductor. In both cases, an external doping atom source is no longer present during the thermal treatment and the particle beam is switched off.

Thermal oxidation of silicon is widely used in semiconductor technology. Silicon located on the surface of the Si crystal is oxidized in an oxygen-containing atmosphere at increased temperatures. This oxide forms an SiO₂/Si interface with the silicon substrate located thereunder. During the oxide growth, silicon is converted into oxide and the interface is moved such that the SiO₂ layer thickness increases. The growth rate thereby reduces since the oxidizing atmosphere components diffuse through constantly thickening oxide layers towards the SiO₂/Si interface. The kinetics of this reaction may depend upon the crystal orientation, doping and upon the oxidizing atmosphere components. For example, by adding water vapor (moist oxidation), the oxidation can be accelerated. Also DCE (trans-1,2-dichloroethylene) can influence the reaction speed (O. Schultz, High-Efficiency Multicrystalline Silicon Solar Cells, Dissertation at the University of Konstanz, Faculty of Physics (2005), p. 103). Furthermore, the kinetics may be influenced by the temperature which prevails during the oxidation.

The SiO₂/Si interface can be configured with suitable process control such that it is passivated. This means that the recombination rate of the minority charge carriers is reduced relative to an unpassivated surface (O. Schultz, High-Efficiency Multicrystalline Silicon Solar Cells, Dissertation at the University of Konstanz, Faculty of Physics (2005), p. 104 ff.).

A process in which impurities can be transferred specifically from one region of the semiconductor into another is termed gettering (A. A. Istratov et al., Advanced Gettering Techniques in UL-SI Technology, MRS Bulletin (2000), pp. 33-38). This process can be performed by different methods. One is phosphorus gettering. During phosphorus diffusion, silicon intermediate lattice atoms that increase the mobility of many types of impurities are produced. Due to the higher solubility of these components in highly-doped silicon regions, these collect during the high temperature step in these areas and the volume of the semiconductor is cleaned.

Since no gettering is observed during pure oxidation, this process is particularly susceptible to impurities, which are located either on or in the substrate, in contaminated process and handling devices or in contaminated process gases or process aids.

### SUMMARY

According to the invention a method for simultaneous doping and oxidizing semiconductor substrates is provided, in which at least one surface of the semiconductor substrate is coated at least in regions with at least one layer including a doping agent. The at least one layer may include a plurality of doping agents. Subsequently, a thermal treatment is then effected in an atmosphere including an oxidant for the semiconductor material, as a result of which diffusion of the doping agent into the volume of the semiconductor substrate is made possible. During the thermal treatment, a partial oxidation of the surface regions of the semiconductor substrate that are not coated with the doping agent layer is likewise effected. Thus two process steps can be combined in a simple manner, which leads to simplification of the overall process.

Preferably, the layer containing the doping agent includes a material such as amorphous silicon, silicon dioxide, silicon carbide, silicon nitride, aluminium oxide, titanium dioxide, tantalum oxide, dielectric materials, ceramic materials having organic compounds that can be altered chemically in the diffusion process, non-stoichiometric modifications of these materials or mixtures of these materials. There may be, with respect to silicon nitride, compounds that deviate from the stoichiometric ratio Si₃N₄.

It is likewise possible, as is known from semiconductor technology, to use substances that are present for example initially in liquid or paste form. These are then deposited on the semiconductor, for example by centrifugation, spraying, dip coating, printing or CVD. Subsequently, a drying step can then follow in which a part of the organic components escape. In a further step, the substance can then be converted into a glass-like consistency which then serves, in the subsequent high-temperature process, as diffusion source or also as barrier. Substances of this type can be produced and processed according to the known sol-gel method.

The doping agent is preferably selected from the group consisting of phosphorus, boron, arsenic, aluminum and gallium.

Preferably, the layer including the doping agent has a concentration gradient with respect to the doping agent, a higher doping agent concentration prevailing in the region orientated towards the semiconductor substrate.

Various alternatives exist with respect to the coating of the semiconductor substrate. Thus a first preferred variant provides that the semiconductor substrate is coated continuously on one surface with a layer including a doping agent and subsequently, by thermal treatment with an atmosphere containing an oxidant, a partial oxidation of the non-coated surfaces, e.g. the rear-side of the semiconductor substrate, is effected. Another variant provides that one or more surfaces of the semiconductor substrate are coated merely in regions with a layer including a doping agent, as a result of which also uncoated regions remain. In the subsequent oxidation step, a partial oxidation of the non-coated surfaces of the semiconductor substrate is then effected.

Basically, the method described herein can be combined at any time with any process steps which are known from processing semiconductor substrates and in particular in the production of solar cells. Hence it is for example possible for the semiconductor substrate to have been treated at least in regions before coating the layer having the doping agent. However it is likewise possible also that a treatment is implemented after coating the layer having the doping agent and before the thermal treatment.

The treatment steps may include wet-chemical or dry-chemical processing, thermal processing, coating, mechanical processing, laser technology processing, metallisation, silicon processing, cleaning, wet- or dry-chemical texturing, removal of texturing and combinations of the mentioned treatment steps. There are here a large number of combinations between the mentioned treatment steps. For example, the semiconductor substrates can be processed after coating with the doping agent with the aim of preparing the uncoated regions for the thermal treatment. This can include for example that existing textures are leveled entirely or partially or that different cleaning processes are implemented. The cleaning can thereby be both of a wet-chemical and dry-chemical nature. Another example concerns the removal at least in regions of existing coatings with the aim of achieving a structuring of the coating or else in order to remove parasitic coatings on for example the rear-side.

A further preferred variant provides that the coated semiconductor substrate is treated wet- or dry-chemically before the thermal treatment. Likewise the possibility exists of etching the uncoated parts of the semiconductor while the coating masks the remaining semiconductor. In this way, suitable starting conditions for the thermal oxidation can be created, in particular a very high passivation quality can be achieved.

A preferred variant provides that a further coating is applied on the semiconductor substrate. Thus for example the layer including the doping agent on the side orientated away from the semiconductor substrate can be provided with a cover layer as a diffusion barrier for the doping agent in order to prevent escape of the doping agent. This cover layer preferably includes a material such as amorphous silicon, silicon dioxide, silicon carbide, silicon nitride, aluminum oxide, titanium dioxide, tantalum oxide, dielectric materials, ceramic materials, materials comprising organic compounds which can be altered chemically in the diffusion process, non-stoichiometric modifications of these materials or mixtures of these materials. In a further preferred variant, the cover layer can also have a multilayer construction in which the different layers include different materials.

In a preferred variant the at least one coating can be effected such that the coating material is deposited in liquid or paste form on the semiconductor substrate or on the coatings already applied on the semiconductor substrate. This can be effected preferably by centrifugation, spraying, dip coating, printing or CVD methods. Subsequently, a drying step can be effected, in which a part of the organic components is removed. In a further step, the coating material can then be converted into a glass-like consistency that serves, during the subsequent high-temperature process, as a diffusion source or as a barrier. Coating materials of this type can also be produced and processed according to the sol-gel method. However, other coating methods and doping methods, as known in the art, can likewise be applied. In this respect, reference is made to S. K. Ghandi, VLSI Fabrication Principles: Silicon and Gallium Arsenide, 2^{nd} edition (1994) chapter 8, pp. 510-586.

A further variant according to the invention provides that, between the semiconductor substrate and the at least one doping agent layer, at least one further layer is applied, through which diffusion of the doping agent into the volume of the semiconductor substrate is not completely suppressed or obstructed. For example, normally a native silicon dioxide layer is formed on silicon, said silicon dioxide layer being so thin that doping of the silicon cannot be masked thereby. It is also possible that other layers are still present from preceding processes or process steps by means of which the diffusion is however not suppressed.

The thermal treatment in the method according to the invention is effected preferably in a tubular furnace or a continuous furnace. However, it is also contemplated that the thermal treatment is implemented directly in a PECVD reactor. The thermal treatment is thereby effected preferably at temperatures in the range of 600 to 1150° C.

Various method variants exist with respect to the oxidation step. Thus a dry oxidation can be implemented using oxygen as oxidant. A further preferred variant provides that a moist oxidation is implemented, i.e. oxygen is used as oxidant in the presence of water vapor. The atmosphere used for the oxidation can contain in addition further compounds for controlling the oxidation process. Likewise, compounds can be added to the atmosphere for maintaining the cleanliness of the same. There is included for this purpose in particular trans-1,2-dichloroethylene.

The semiconductor substrate may include silicon, germanium or gallium arsenide. Likewise, already doped semiconductor substrates, which are doped e.g. with phosphorus, boron, arsenic, aluminum and/or gallium, can also be used. However it is preferred in particular that the semiconductor substrate in the regions close to the surface has, in addition to already present dopings, at most a slight doping which stems from the previously deposited doping agent source and has been formed by an additional thermal treatment before the simultaneous diffusion and oxidation. In the final thermal treatment, the diffusion of these doping agents is then reinforced.

It is likewise possible that the semiconductor substrate, even before implementation of the method according to the invention has structures at least in regions, e.g. in the form of masking, that suppress or obstruct thermal oxidation of the semiconductor substrate in these regions.

A further variant according to the invention provides that, during the process, a gettering process is implemented by enriching impurities in doped regions in the semiconductor substrate. This is possible in particular during doping with phosphorus in the thermal process. Gettering takes place during phosphorus diffusion as a side effect. The impurities diffuse into the regions of high phosphorus concentrations since they are more soluble there than in the remaining volume. They have less influence on the semiconductor component there. In the case of a pure oxidation process, as is known from the state of the art, no gettering process results so that very high purity requirements must be maintained here. Hence the method according to the invention, relative to the state of the art, also has the advantage that, with respect to the purity conditions, high requirements of this type do not require to be maintained, which can be attributed to the gettering process taking place in parallel.

According to the invention, a doped and oxidized semiconductor substrate which can be produced according to the above-described method is likewise provided.

The above-described method is used in particular in the production of solar cells.

### BRIEF DESCRIPTION OF THE FIGURES

FIG. 1 is a schematic illustration of an assembly in accordance with the invention;

FIG. 2 is a schematic illustration of an assembly in accordance with the invention;

FIG. 3 is a schematic illustration of an assembly in accordance with the invention;

FIG. 4 is a schematic illustration of an assembly in accordance with the invention;

FIG. 5 is a schematic illustration of an assembly in accordance with the invention;

FIG. 6 is a schematic illustration of an assembly in accordance with the invention;

FIG. 7 is a schematic illustration of an assembly in accordance with the invention;

FIG. 8 is a schematic illustration of an assembly in accordance with the invention;

FIG. 9 is a schematic illustration of an assembly in accordance with the invention;

FIG. 10 is a schematic illustration of an assembly in accordance with the invention; and

FIG. 11 is a schematic illustration of an assembly in accordance with the invention.

### DETAILED DESCRIPTION

The invention is intended to be represented subsequently by an example of a boron-doped silicon substrate as semiconductor substrate and a phosphorus-containing silicon dioxide as doping agent source.

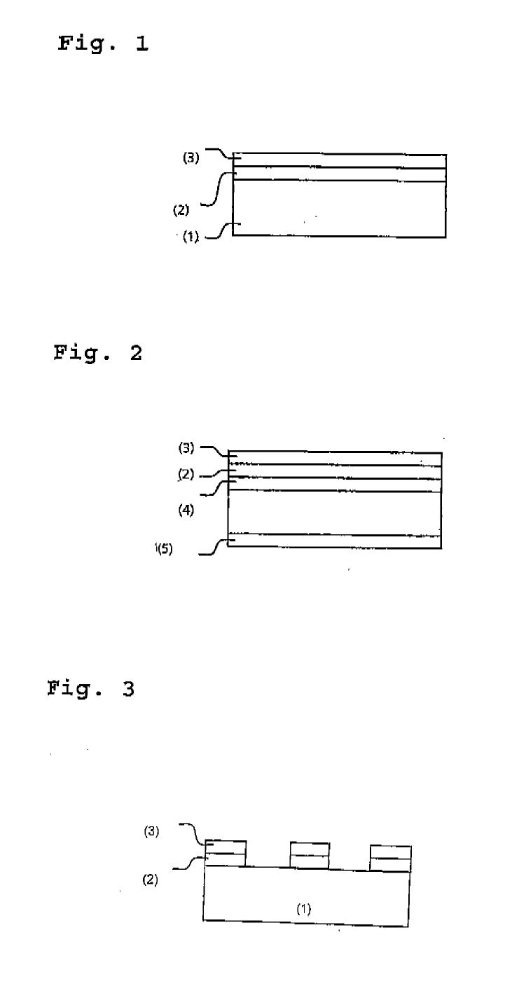

The silicon wafer 1 is coated on one side for example in a so-called PECVD coating plant with a phosphorus-containing silicon oxide 2 (FIG. 1).

The silicon oxide 2 serves as phosphorus source and layer 3 as barrier against escaping phosphorus. The other side of the disc remains uncoated. The thus-uncoated disc can now be cleaned again in order to pretreat the uncoated side for the subsequent thermal process. This cleaning can be implemented by wet- or dry technology. If steps which attack the layer 3 are included in this cleaning, these steps are chosen to be brief such that the property of the layer 3 to serve as diffusion barrier is not lost. Correspondingly, the layer can also be formed to be suitably thick.

A high-temperature step follows in which the side coated with layer 2, the phosphorus from layer 2 penetrates into the silicon and a suitable doping concentration 4 is achieved in the wafer. Simultaneously a thermally grown silicon dioxide 5 is formed on the non-coated regions of the wafer (FIG. 2). This silicon dioxide is produced if the atmosphere in the furnace in which the high-temperature process is implemented contains oxygen. In addition to the oxygen, also water vapor or other suitable substances can be contained in the atmosphere, which enable the oxidation process or have an advantageous effect such as accelerating the oxidation process. The layers 2 and 3 can also be combined to form one layer that has a suitable course of the concentration of the doping agent so that the latter is prevented from escaping from the layer into the process atmosphere to an undesired extent such that the side to be oxidized is not disadvantageously effected by escaping doping agent.

As already described above, coating in regions is also possible. This can be effected by using corresponding masks or even by targeted back-etching. In FIG. 3, a silicon wafer 1 is represented before the thermal treatment for simultaneous diffusion and oxidation. A first surface here has regions with a phosphorus-containing silicon oxide layer 2. The silicon oxide 2 thereby serves as phosphorus source. At the same time, cover layers made of silicon dioxide 3 are deposited on these regions. Due to the thermal treatment for diffusion and oxidation, a structure is then obtained as is represented in FIG. 4. This high-temperature step has the effect that the phosphorus from layer 2 penetrates into the silicon wafer 1 on the side coated with layer 2 and a suitable doping concentration 4 in the wafer is achieved. At the same time, a thermally grown silicon dioxide 5 is formed on the non-coated regions of the wafer.

The above-described invention can be used in various ways, for example for the production of solar cells. Two possible process variants are represented subsequently:

### Process Variant A

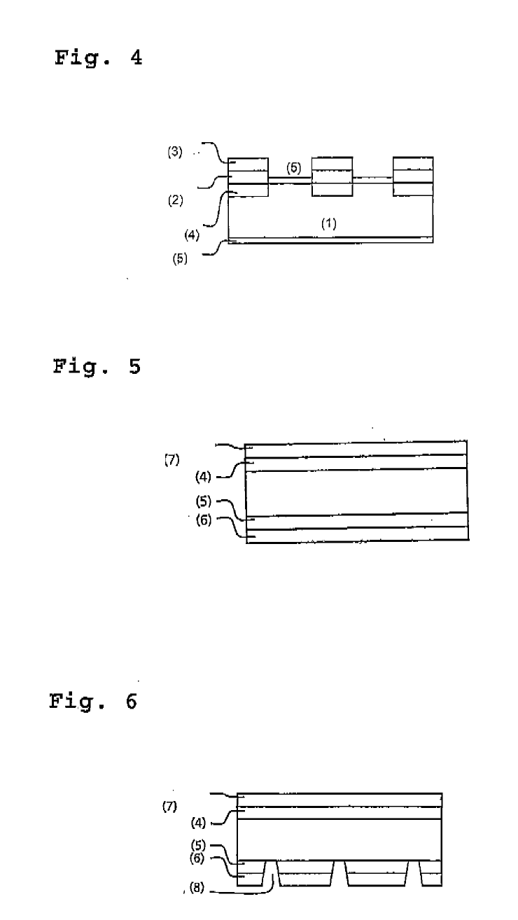

A rear-side suitable cover layer is applied, followed by an etching step in which the layers 2 and 3 are removed. The cover layer thereby protects the layer 5 situated thereunder. The material choice for this layer is very wide. The layer can include for example a dielectric, a metal, a ceramic material or a layer system. Subsequently, an antireflection coating 7 is deposited on the front-side of the wafer (FIG. 5).

Thereafter, the rear-side layer system is opened locally with a suitable method, e.g. with a laser (FIG. 6).

Subsequently, a suitable contact paste is disposed, e.g. by means of screen printing, with a suitable method on the front-side and on the rear-side in a freely selectable sequence. Pastes which allow a simple subsequent wiring of the solar cells in modules can also be combined on the rear-side (FIG. 7).

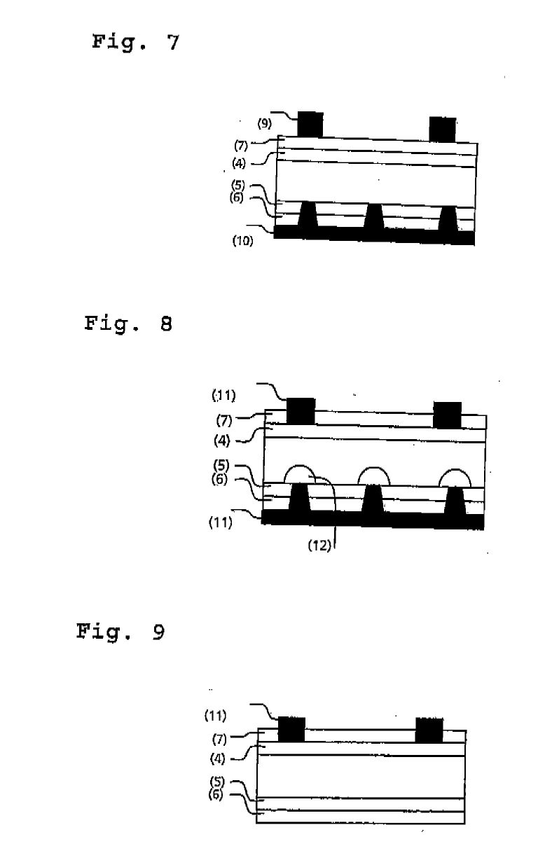

In the subsequent step, the contacts are formed in that the silicon disc is subjected to a suitable thermal process. This so-called contact sintering can be implemented for example in a sintering furnace, as is known already at the present time in solar cell production technology (FIG. 8).

The production process of the solar cell is now substantially concluded. Further process steps with which the component is finished can also be introduced or added here. For example, wet chemical surface treatments can take place initially in order to reduce the reflection of the silicon disc by means of a so-called texturing. In addition, thermal healing steps or laser processes for edge insulation can be applied.

### Process Variant B

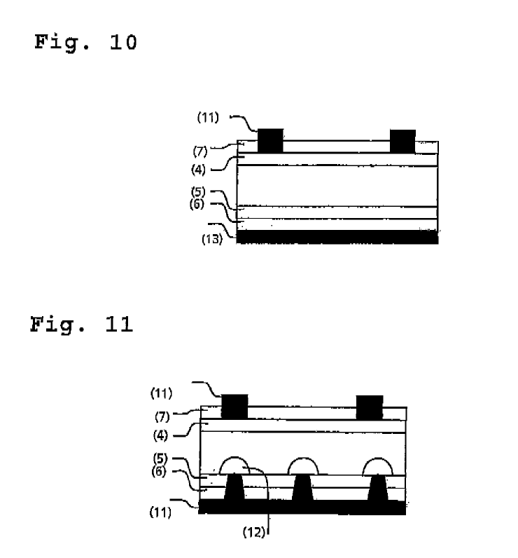

After depositing the antireflection coating according to FIG. 3 in variant A, the contact paste is disposed here on the front-side. The disc is subsequently treated in a suitable thermal process, the front-side contact being formed (FIG. 9).

Subsequently, a suitable metal layer is disposed on the rear-side of the solar cell. This step can also be combined with the preceding step. However, it is useful that the metal layer does not penetrate the layer sequence situated thereunder as far as the silicon (FIG. 10).

Finally, the rear-side metal layer is processed with a laser in such a manner that it penetrates the layer sequence situated thereunder on regions provided for this purpose and produces an electrical contact to the silicon. If the metal layer is for example aluminum-containing, then it can also form a local p++ doping at the points of the laser processing.

The production process of the solar cell is now substantially concluded. Further process steps with which the component is finished can also be introduced or added here. For example wet chemical surface treatments can take place initially in order to reduce the reflection of the silicon disc by means of a so-called texturing. Furthermore, thermal healing steps or laser processes for edge insulation can be applied.

1-30. (canceled)

31. A method for simultaneous doping and oxidizing a semiconductor substrate having at least one surface, the method comprising the steps of:
coating at least a region of the at least one surface with a layer comprising at least one doping agent; and
subjecting the semiconductor substrate to a thermal treatment in an atmosphere comprising an oxidant for the semiconductor substrate;
wherein the doping agent diffuses into a volume of the semiconductor substrate and uncoated surface regions of the semiconductor substrate are oxidized as a result of the thermal treatment.

32. The method of claim 31, wherein the layer comprising the doping agent comprises a material selected from the group consisting of amorphous silicon, silicon dioxide, silicon carbide, silicon nitride, aluminum oxide, titanium dioxide, tantalum oxide, dielectric materials, ceramic materials, materials comprising organic compounds which can be altered chemically in the diffusion process, non-stoichiometric modifications of these materials and mixtures of these materials.

33. The method of claim 31, wherein the doping agent comprises a material selected from the group consisting of phosphorus, boron, arsenic, aluminum and gallium.

34. The method of claim 31, wherein the layer comprising the doping agent has a concentration gradient with respect to the doping agent, a higher doping agent concentration prevailing in a region orientated towards the semiconductor substrate.

35. The method of claim 31, wherein the at least one surface is coated with a layer comprising at least one doping agent.

36. The method of claim 31, further comprising subjecting regions of the semiconductor substrate to at least one further treatment step prior to coating the layer comprising the doping agent.

37. The method of claim 36, wherein the at least one further treatment step is selected from the group consisting of wet-chemical or dry-chemical processing, thermal processing, coating, mechanical processing, laser technology processing, metallization, silicon processing, cleaning, wet- or dry-chemical texturing, removal of texturing and also combinations of the mentioned treatment steps.

38. The method of claim 31, further comprising subjecting regions of the semiconductor substrate to at least one further treatment step after coating the layer comprising the doping agent but before subjecting the semiconductor substrate to the thermal treatment.

39. The method of claim 37, wherein the at least one further treatment step is selected from the group consisting of wet-chemical or dry-chemical processing, thermal processing, coating, mechanical processing, laser technology processing, metallization, silicon processing, cleaning, wet- or dry-chemical texturing, removal of texturing and also combinations of the mentioned treatment steps.

40. The method of claim 31, further comprising a step of applying at least one further coating to the semiconductor substrate.

41. The method of claim 31, wherein the layer comprising the doping agent includes, on a side of the layer opposite the semiconductor substrate, a cover layer as a diffusion barrier for the doping agent.

42. The method of claim 41, wherein the cover layer comprises a material selected from the group consisting of amorphous silicon, silicon dioxide, silicon carbide, silicon nitride, aluminum oxide, titanium dioxide, tantalum oxide, dielectric materials, ceramic materials, materials comprising organic compounds which can be altered chemically in the diffusion process, non-stoichiometric modifications of these materials and mixtures of these materials.

43. The method of claim 41, wherein the cover layer has a multilayer construction.

44. The method of claim 31, wherein coating with a layer comprising at least one doping agent comprises applying a coating material in liquid or paste form.

45. The method of claim 44, further comprising drying the coating material to form a glass-like consistency.

46. The method of claim 44, wherein coating with a layer comprising at least one doping agent comprises centrifugation, spraying, dip coating, printing and/or chemical vapor deposition.

47. The method of claim 44, wherein the coating material comprises a sol-gel.

48. The method of claim 31, further comprising applying at least one further layer between the semiconductor substrate and the layer comprising at least one doping agent, the at least one further layer permitting diffusion of the doping agent therethrough.

49. The method of claim 31, wherein the thermal treatment comprises use of a tubular furnace or a continuous furnace.

50. The method of claim 31, wherein the thermal treatment is implemented at a temperature in a range of 600° C. to 1150° C.

51. The method of claim 31, wherein a dry oxidation is performed using oxygen as the oxidant.

52. The method of claim 31, wherein a moist oxidation is performed using oxygen as the oxidant in the presence of water vapor.

53. The method of claim 31, wherein the atmosphere comprises further compounds for controlling oxidation or for maintaining cleanliness of the atmosphere.

54. The method of claim 54, wherein the atmosphere comprises trans-1,2-dichloroethylene.

55. The method of claim 31, wherein the semiconductor substrate comprises silicon, germanium or gallium arsenide.

56. The method of claim 31, wherein the semiconductor substrate is doped with phosphorus, boron, arsenic, aluminum and/or gallium.

57. The method of claim 31, wherein the semiconductor substrate includes a doping prior to being coated with a layer comprising at least one doping agent.

58. The method of claim 31, wherein the semiconductor substrate has structures at least in regions which suppress or obstruct thermal oxidation of the semiconductor substrate in these regions.

59. The method of claim 31, further comprising a gettering process to enrich impurities in doped regions in the semiconductor substrate.
